(19) United States
(12) Patent Application Publication
(10) Pub. No.: US 2026/0164830 A1
(43) Pub. Date: Jun. 11, 2026

(54) IMAGE SENSOR

(71) Applicant: SK hynix Inc., Icheon-si (KR)

(72) Inventor: Sung Wook CHO, Icheon-si (KR)

(21) Appl. No.: 19/196,272

(22) Filed: May 1, 2025

(30) Foreign Application Priority Data
Dec. 10, 2024 (KR) 10-2024-0183141

(51) Int. Cl. H10F 39/00

(52) U.S. Cl. CPC H10F 39/807; H10F 39/8053; H10F 39/8063

(57) ABSTRACT

The image sensor is provided to including a semiconductor substrate including first pixel regions connected to a first shared region and second pixel regions connected to a second shared region; a plurality of first inner isolation walls extending between neighboring first pixel regions within the semiconductor substrate and disposed to provide a first opening that exposes the first shared region; and a plurality of second inner isolation walls extending between neighboring second pixel regions within the semiconductor substrate and disposed to provide a second opening that exposes the second shared region. A first width of the first opening in the first shared region and between facing first inner isolation walls may be different from a second width of the second opening in the second shared region and between facing second inner isolation walls.

### PRIORITY CLAIM AND CROSS-REFERENCE TO RELATED APPLICATIONS

The present application claims priority under 35 U.S.C. § 119(a) to Korean Application No. 10-2024-0183141, filed in the Korean Intellectual Property Office on Dec. 10, 2024, the entire contents of which are incorporated herein by reference.

### TECHNICAL FIELD

The present disclosure generally relates to a semiconductor device, and more particularly, to an image sensor including an isolation structure.

### BACKGROUND

An image sensor is a semiconductor device that converts optical images into electrical signals. Image sensors are applied to various technical fields such as digital cameras, camcorders, mobile phones, robots, automobiles, etc. Image sensors are evolving toward low power consumption, fast data processing, and high-quality images.

### SUMMARY

An embodiment of the present disclosure may describe an image sensor including a semiconductor substrate including a plurality of first pixel regions connected to a first shared region and a plurality of second pixel regions connected to a second shared region, each of the first pixel regions and second pixel regions structured to detect incident light to generate an electrical pixel signal representing the detected incident light; a plurality of first inner isolation walls extending between neighboring first pixel regions within the semiconductor substrate and disposed to provide a first opening that exposes the first shared region; and a plurality of second inner isolation walls extending between neighboring second pixel regions within the semiconductor substrate and disposed to provide a second opening that exposes the second shared region. A first width of the first opening in the first shared region and between facing first inner isolation walls may be different from a second width of the second opening in the second shared region and between facing second inner isolation walls.

An embodiment of the present disclosure may describe an image sensor including a semiconductor substrate including a plurality of first pixel regions connected to a first shared region, a plurality of second pixel regions connected to a second shared region, and a plurality of third pixel regions connected to a third shared region; a plurality of first inner isolation walls extending between neighboring first pixel regions within the semiconductor substrate and providing a first opening that exposes the first shared region; a plurality of second inner isolation walls extending between neighboring second pixel regions within the semiconductor substrate and providing a second opening that exposes the second shared region; a plurality of third inner isolation walls extending between neighboring third pixel regions within the semiconductor substrate and providing a third opening that exposes the third shared region; a first color filter disposed on the first shared region and the first pixel regions; a second color filter disposed on the second shared region and the second pixel regions; and a third color filter disposed on the third shared region and the third pixel regions. A first width of the first opening in the first shared region and between facing first inner isolation walls may be smaller than a second width of the second opening in the second shared region and between facing second inner isolation walls and a third width of the third opening and between facing third inner isolation walls.

### BRIEF DESCRIPTION OF THE DRAWINGS

FIG. 1 is a schematic view illustrating an image sensor according to an embodiment of the present disclosure.

FIG. 2 is a schematic cross-sectional view illustrating a cross-sectional shape of an image sensor according to an embodiment, taken along line C1-C1′ in FIG. 1.

FIG. 3 is a schematic cross-sectional view illustrating a cross-sectional shape of an image sensor according to an embodiment, taken along line C2-C2′ in FIG. 1.

FIG. 4 is a schematic plan view illustrating a planar shape of an image sensor according to an embodiment, with some portions in FIG. 1 enlarged.

FIG. 5 is a schematic view illustrating an image sensor according to an embodiment of the present disclosure.

FIG. 6 is a schematic cross-sectional view illustrating a cross-sectional shape of an image sensor according to an embodiment, taken along line C1-C1′ in FIG. 5.

FIG. 7 is a schematic cross-sectional view illustrating a cross-sectional shape of an image sensor according to an embodiment, taken along line C2-C2′ in FIG. 5.

FIG. 8 is a schematic view illustrating an image sensor according to an embodiment of the present disclosure.

FIG. 9 is a schematic cross-sectional view illustrating a cross-sectional shape of an image sensor according to an embodiment, taken along line C3-C3′ in FIG. 8.

FIG. 10 is a schematic cross-sectional view illustrating a cross-sectional shape of an image sensor according to an embodiment, taken along line C4-C4′ in FIG. 8.

FIG. 11 is a schematic view illustrating an image sensor according to an embodiment of the present disclosure.

### DETAILED DESCRIPTION

The cross-hatching throughout the figures illustrates corresponding or similar areas between the figures rather than indicating the materials associated with the areas.

In the description of the present disclosure, descriptions such as “first,” “second,” “third,” etc. are used to distinguish components, and are not used to limit the components themselves or to imply a specific order. In the description of the present disclosure, terms such as “front side,” “back side,” etc., do not limit a specific direction, location, or component. Terms such as “below,” “beneath,” “lower,” “above,” “upper,” etc., can be used to describe the spatial relative location between components.

Throughout the specification, the same reference numerals may refer to the same components. The same reference numerals or similar reference numerals may be described with reference to other drawings, even if they are not mentioned or described in the drawings. Also, even if the reference numerals are not indicated, they may be described with reference to other drawings.

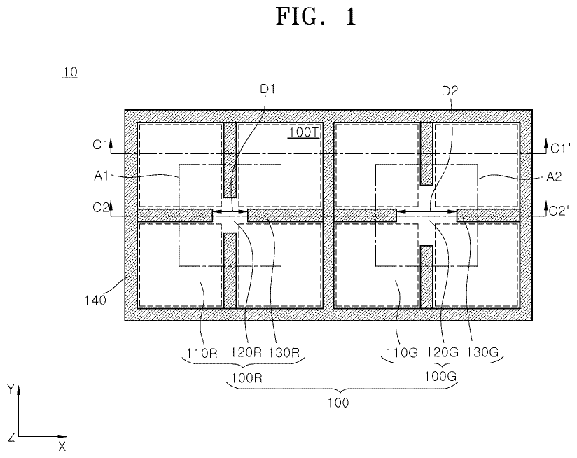

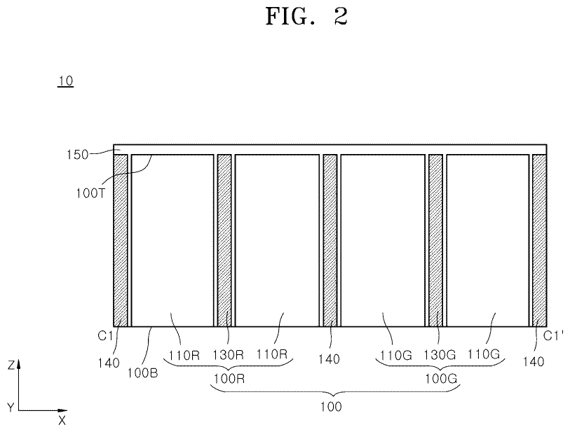

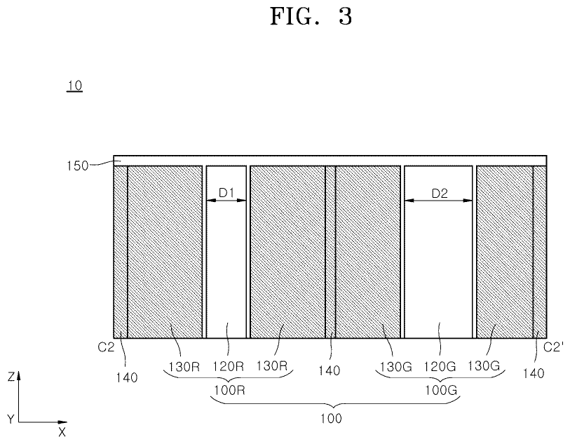

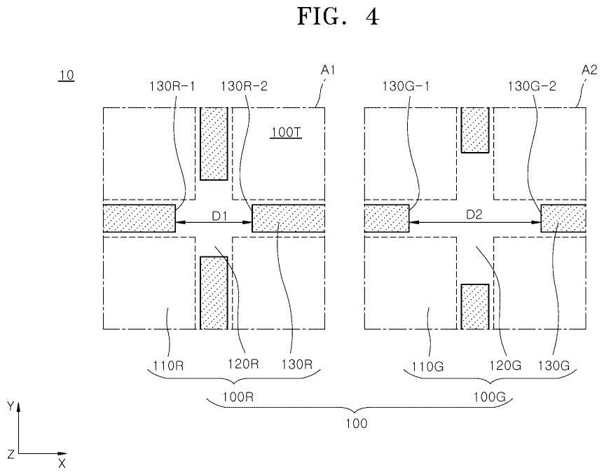

FIG. 1 is a schematic plan view illustrating an image sensor 10 according to an embodiment of the present disclosure. FIG. 1 schematically illustrates a pixel array of the image sensor 10 according to an embodiment. FIG. 2 is a schematic cross-sectional view illustrating a cross-sectional shape of the image sensor 10 taken along line C1-C1′ in FIG. 1. FIG. 3 is a schematic cross-sectional view illustrating a cross-sectional shape of the image sensor 10 taken along line C2-C2′ in FIG. 1. FIG. 4 is a schematic plan view illustrating an enlarged view of portion A1 and portion A2 in FIG. 1.

Referring to FIG. 1, the image sensor 10 includes a pixel array in which a plurality of pixel regions 110R and 110G are arranged. Each of the plurality of pixel regions 110R and 110G is configured to generate image signals corresponding to objects. Each of the plurality of pixel regions 110R and 110G includes a photoelectric conversion element that produce an electrical signal in response to received light. The photoelectric conversion element includes a photodiode, a photo transistor, a photo gate, or other photosensitive circuitry capable of converting light into a pixel signal (e.g., a charge, a voltage or a current). In the description below, the photodiode is described as an example of the photoelectric conversion element and other implementations are also possible.

FIG. 1 illustrates a shape in which the pixel regions 110R and 110G are arranged on an X-Y plane of a semiconductor substrate 100. The X-Y plane is a surface or a top surface of the semiconductor substrate 100, represented by an X-axis and a Y-axis orthogonal to each other. The semiconductor substrate 100 is a substrate on which elements constituting the image sensor or photodiodes are formed. The semiconductor substrate 100 includes a semiconductor material such as silicon (Si), silicon germanium (SiGe), and so forth. The semiconductor substrate 100 has a shape of a semiconductor wafer or a semiconductor die. The semiconductor substrate 100 includes an epitaxial layer of a semiconductor material. Each of the pixel regions 110R and 110G include regions of the semiconductor substrate 100 doped with dopants that constitute a photodiode. The dopants include P-type impurities or N-type impurities.

The semiconductor substrate 100 includes a group of first pixel regions 110R that are adjacent to one another and a separate group of second pixel regions 110G that are adjacent to one another. Each of the first pixel regions 110R and each of the second pixel regions 110G may include photoelectric conversion or transformation elements (e.g., photodiodes) formed substantially identically for detecting incident light. The first pixel regions 110R are connected to each other through a first shared region 120R that is shared by the adjacent first pixel regions 110R. The first shared region 120R is a coupling region that connects the plurality of first pixel regions 110R. The first shared region 120R is a coupling region that connects the photoelectric conversion or transformation elements (e.g., photodiodes) formed in each of the first pixel regions 110R. The first pixel regions 110R are disposed to surround the first shared region 120R with the first shared region 120R at a center. In the semiconductor substrate 100, the first pixel regions 110R are disposed such that four first pixel regions 110R surround the first shared region 120R with respect to the first shared region 120R. In each of the first pixel regions 110R and in each of the second pixel regions 110G, the regions doped with dopants, which constitute the photodiodes, extend into the first shared region 120R.

The second pixel regions 110G are separated from the first pixel regions 110R as shown the different second pixel regions 110G are connected to each other through a second shared region 120G that is shared by the adjacent second pixel regions 110G. The second shared region 120G is a coupling region that connects the plurality of second pixel regions 110G. The second shared region 120G is a coupling region that connects the photoelectric conversion or transformation elements (e.g., photodiodes) formed in each of the second pixel regions 110G to each other. The second pixel regions 110G are disposed to surround the second shared region 120G with the second shared region 120G at a center. In the semiconductor substrate 100, the second pixel regions 110G are disposed such that four second pixel regions 110G surround the second shared region 120G with respect to the second shared region 120G.

The plurality of first pixel regions 110R connected to the first shared region 120R constitute a first pixel group 100R, and the plurality of second pixel regions 110G connected to the second shared region 120G constitute a second pixel group 100G. The first pixel group 100R including the first pixel regions 110R and the first shared region 120R and the second pixel group 100G including the second pixel regions 110G and the second shared region 120G are alternately repeated along X-axis direction. The first pixel group 100R and the second pixel group 100G are alternately repeated along Y-axis direction. The first pixel groups 100R are repeated along a diagonal direction between the X-axis and the Y-axis, and the second pixel groups 100G are repeated along a diagonal direction between the X-axis and the Y-axis. The diagonal direction in which the first pixel groups 100R are repeated and the diagonal direction in which the second pixel groups 100G are repeated are parallel and spaced apart from each other.

Referring to FIG. 1, FIG. 2, and FIG. 3, a plurality of first inner isolation walls 130R are disposed to extend between neighboring first pixel regions 110R within the semiconductor substrate 100. The first inner isolation walls 130R are disposed to separate the neighboring first pixel regions 110R. The first inner isolation walls 130R block light incident into the first pixel region 110R from proceeding to the neighboring first pixel regions 110R. The first inner isolation walls 130R restrict the light incident into the first pixel regions 110R from undesirably escaping to other pixel regions. The semiconductor substrate 100 includes a light receiving surface 100T on which the light is incident and an opposite surface 100B on the opposite side, as shown in FIG. 2. The plurality of first inner isolation walls 130R are disposed within the semiconductor substrate 100 to extend from the light receiving surface 100T of the semiconductor substrate 100 to the opposite surface 100B.

The plurality of first inner isolation walls 130R are disposed in the semiconductor substrate 100 to open the first shared region 120R. The first shared region 120R is exposed to the light receiving surface 100T of the semiconductor substrate 100 without being covered by the first inner isolation walls 130R. Accordingly, when light is incident into the first pixel regions 110R, the light may also be incident into the first shared region 120R. Electrons are generated by the light incident into the first shared region 120R, and the electrons are introduced into the first pixel regions 110R. Because the electrons generated in response to the first shared region 120R are additionally introduced into the first pixel regions 110R, optical loss in the first pixel regions 110R may be reduced. The first shared region 120R may reduce optical loss in the first pixel regions 110R connected to the first shared region 120R, thereby improving light sensitivity in the first pixel regions 110R. The first shared region 120R may increase the light receiving regions within the first pixel group 100R, thereby improving the light sensitivity in the first pixel regions 110R.

The first inner isolation walls 130R are disposed radially with the first shared region 120R at a center. When viewed from the light receiving surface 100T of the semiconductor substrate 100, some of the first inner isolation walls 130R extend in a first direction, and others of the first inner isolation walls 130R extend in a second direction intersecting the first direction. The first direction may be the X-axis direction in an X-Y plane, and the second direction may be the Y-axis direction.

A plurality of second inner isolation walls 130G are disposed to extend between neighboring second pixel regions 110G within the semiconductor substrate 100. The second inner isolation walls 130G are disposed to separate the second pixel regions 110G. The second inner isolation walls 130G block light incident into the second pixel regions 110G from proceeding to the neighboring second pixel regions 110G. The second inner isolation walls 130G physically separate the light incident into the second pixel regions 110G, thereby reducing or preventing light sensitivity imbalance between the second pixel regions 110G. The plurality of second inner isolation walls 130G are disposed in the semiconductor substrate 100 to extend from the light receiving surface 100T of the semiconductor substrate 100 to the opposite surface 100B.

The plurality of second inner isolation walls 130G are disposed in the semiconductor substrate 100 to open the second shared region 120G. The second shared region 120G is exposed to the light receiving surface 100T of the semiconductor substrate 100 without being covered by the second inner isolation walls 130G. Accordingly, when light is incident into the second pixel regions 110G, the light may also be incident into the second shared region 120G. Electrons are generated by the light incident into the second shared region 120G, and the electrons are introduced into the second pixel regions 110G. Because the electrons generated in response to the second shared region 120G are additionally introduced into the second pixel regions 110G, optical loss in the second pixel regions 110G may be reduced. The second shared region 120G may reduce optical loss in the second pixel regions 110G connected to the second shared region 120G, thereby improving light sensitivity in the second pixel regions 110G. The second shared region 120G may increase the light receiving region in the second pixel group 100G, thereby improving the light sensitivity in the second pixel regions 110G.

The second inner isolation walls 130G are disposed radially with the second shared region 120G at a center. When viewed from the light receiving surface 100T of the semiconductor substrate 100, some of the second inner isolation walls 130G extend in the first direction, and others of the second inner isolation walls 130G extend in the second direction intersecting the first direction. The first direction may be the X-axis direction in the X-Y plane, and the second direction may be the Y-axis direction.

An outer isolation wall 140 is disposed within the semiconductor substrate 100. When viewed from the light receiving surface 100T of the semiconductor substrate 100, the outer isolation wall 140 is disposed in the semiconductor substrate 100 to surround the first pixel regions 110R, the first shared region 120R, and the first inner isolation walls 130R. The outer isolation wall 140 may be disposed to surround the outer perimeters of the first pixel regions 110R. The outer isolation wall 140 extends to surround the second pixel regions 110G, the second shared region 120G, and the second inner isolation walls 130G within the semiconductor substrate 100. The outer isolation wall 140 may be disposed to surround the outer perimeters of the second pixel regions 110G. The outer isolation wall 140 extends to be disposed between the first pixel regions 110R and the second pixel regions 110G to separate the first pixel regions 110R and the second pixel regions 110G from each other.

When viewed from the light receiving surface 100T of the semiconductor substrate 100, the plurality of first inner isolation walls 130R extend from the outer isolation wall 140 toward the first shared region 120R. When viewed from the light receiving surface 100T of the semiconductor substrate 100, the plurality of second inner isolation walls 130G extend from the outer isolation wall 140 toward the second shared region 120G.

The outer isolation wall 140 is disposed in the semiconductor substrate 100 to surround the first pixel group 100R and the second pixel group 100G. When viewed from the light receiving surface 100T of the semiconductor substrate 100, the outer isolation wall 140 has a shape of a lattice extending in the first direction and the second direction intersecting each other. The first direction may be the X-axis direction on the X-Y plane, and the second direction may be the Y-axis direction. The first pixel regions 110R, the first shared region 120R, and the first inner isolation walls 130R are disposed within one lattice of the outer isolation wall 140, and the second pixel regions 110G, the second shared region 120G, and the second inner isolation walls 130G are disposed within another neighboring lattice.

In implementations, widths of the lattices of the outer isolation wall 140 may be made to be substantially the same. The width of each of the lattices of the outer isolation wall 140 is a distance between two portions of the outer isolation wall 140, which face each other in the X-axis direction or the Y-axis direction when viewed from the light receiving surface 100T of the semiconductor substrate 100. The width of the outer isolation wall 140 on the light receiving surface 100T of the semiconductor substrate 100 is substantially the same as the width of each of the first and second inner isolation walls 130R and 130G. The widths of the outer isolation wall 140 and the first and second inner isolation walls 130R and 130G indicate the width in a direction perpendicular to the direction in which the outer isolation wall 140 and the first and second inner isolation walls 130R and 130G extend from the light receiving surface 100T of the semiconductor substrate 100.

The outer isolation wall 140 is disposed within the semiconductor substrate 100 to extend from the light receiving surface 100T of the semiconductor substrate 100 to the opposite surface 100B. When viewed from the light receiving surface 100T of the semiconductor substrate 100, the first inner isolation walls 130R are disposed to have one end connected to the outer isolation wall 140 and extend from the outer isolation wall 140 toward the first shared region 120R. When viewed from the light receiving surface 100T of the semiconductor substrate 100, the second inner isolation walls 130G are disposed to have one end connected to the outer isolation wall 140 and extend from the outer isolation wall 140 toward the second shared region 120G.

In some implementations, the outer isolation wall 140 may be formed as a deep trench isolation (DTI) structure. The first and second inner isolation walls 130R and 130G may be formed as the deep trench isolation (DTI) structure. The deep trench isolation (DTI) structure is formed in a shape extending substantially vertically from the light receiving surface 100T of the semiconductor substrate 100 to the opposite surface 100B. The outer isolation wall 140 includes a material having a lower refractive index than the semiconductor substrate 100. Each of the first and second inner isolation walls 130R and 130G includes a material having lower refractive index than the semiconductor substrate 100. The outer isolation wall 140 includes an undoped polysilicon layer, a silicon oxide layer, a silicon nitride layer, an air structure including empty spaces, or a combination thereof. In an embodiment, the first and second inner isolation walls 130R and 130G include substantially the same material as the outer isolation wall 140.

A protection layer 150 is disposed as a passivation layer that surrounds the first and second inner isolation walls 130R and 130G and the outer isolation wall 140. The protection layer 150 extends to cover the light receiving surface 100T of the semiconductor substrate 100. In an embodiment, the protection layer 150 includes silicon oxide.

Referring to FIG. 1 and FIG. 4, when viewed from the light receiving surface 100T of the semiconductor substrate 100, the first shred region 120R has a first width D1, and the second shared region 120G has a second width D2 different from the first width D1. The first width D1 of the first shared region 120R is a spacing between facing first inner isolation walls 130R. The second width D2 of the second shared region 120G is a spacing between facing second inner isolation walls 130G.

The first width D1 of the first shared region 120R is the spacing between ends 130R-1 and 130R-2 of the first inner isolation walls 130R that face each other in a direction in which the first inner isolation walls 130R extend. In an embodiment, two first inner isolation walls 130R are extended in the same direction and disposed on the same extension line so that the ends 130R-1 and 130R-2 face each other. The two first inner isolation walls 130R are disposed along the X-axis direction, and the first width D1 of the first shared region 120R is a spacing between the ends 130R-1 and 130R-2 of the first inner isolation walls 130R that face each other in the X-axis direction. The spacing in the Y-axis direction between the other two first inner isolation walls 130R spaced apart from each other in the Y-axis direction is substantially the same as the first width D1.

The second width D2 of the second shared region 120G is a spacing between ends 130G-1 and 130G-2 of the second inner isolation walls 130G that face each other in a direction in which the second inner isolation walls 130G extend. Because the second inner isolation walls 130G extend in the X-axis direction and the Y-axis direction, the second width D2 of the second shared region 120G is the spacing in the X-axis direction between two second inner isolation walls 130G disposed such that the ends 130G-1 and 130G-2 of the second inner isolation walls 130G face each other in the X-axis direction.

When viewed from the light receiving surface 100T of the semiconductor substrate 100, the first inner isolation walls 130R and the second inner isolation walls 130G are disposed within the semiconductor substrate 100 such that the first width D1 of the first shared region 120R and the second width D2 of the second shared region 120G are different from each other. Accordingly, the first shared region 120R has an area different from an area of the second shared region 120G on the light receiving surface 100T of the semiconductor substrate 100. Accordingly, the first pixel group 100R and the second pixel group 100G have light receiving regions with different sizes on the light receiving surface 100T of the semiconductor substrate 100. The light receiving region of the first pixel group 100R includes the first shared region 120R and the first pixel regions 110R on the light receiving surface 100T of the semiconductor substrate 100, and the light receiving region of the second pixel group 100G includes the second shared region 120G and the second pixel regions 110G on the light receiving surface 100T of the semiconductor substrate 100. Accordingly, the first shared region 120R has a different area from the second shared region 120G, and thus, it is possible to induce the first pixel group 100R and the second pixel group 100G to have the light receiving regions of the different size.

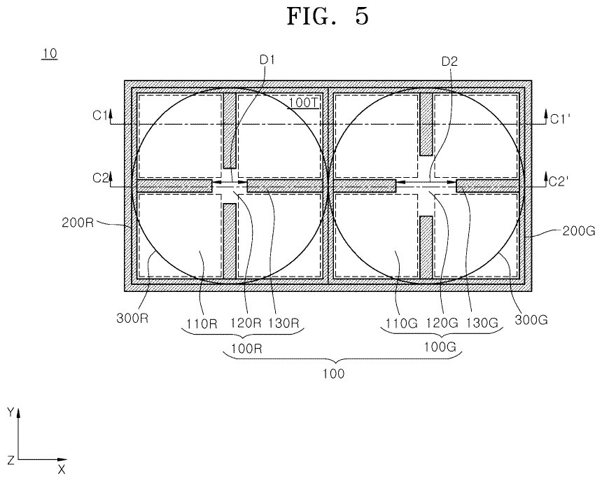

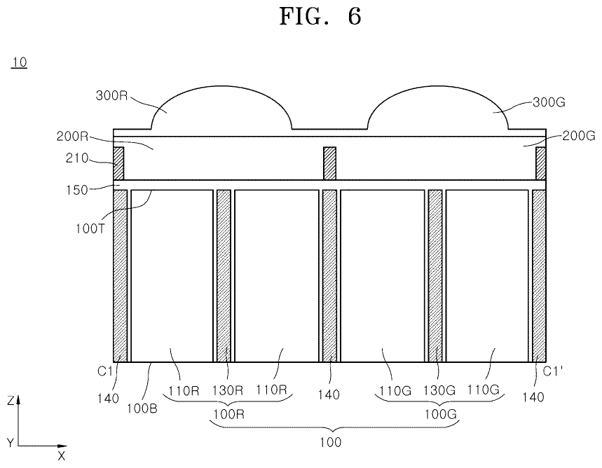

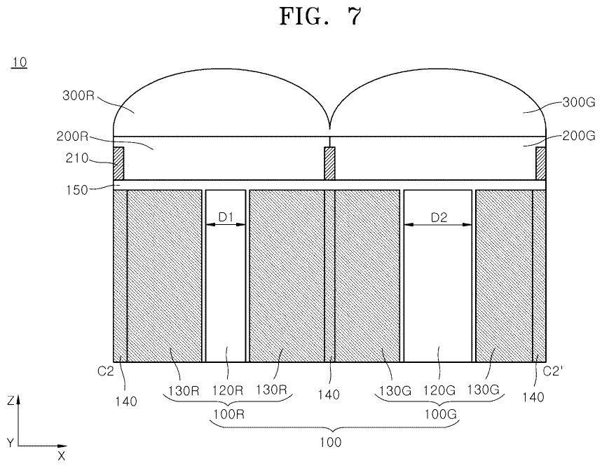

FIG. 5 is a schematic plan view illustrating an image sensor 10 according to an embodiment of the present disclosure, for example, as shown in FIG. 1. FIG. 5 schematically illustrates a color filter array and a micro-lens array of the image sensor 10 according to an embodiment. FIG. 6 is a schematic cross-sectional view illustrating a cross-sectional shape of the image sensor 10 taken along line C1-C1′ in FIG. 5. FIG. 7 is a schematic cross-sectional view illustrating a cross-sectional shape of the image sensor 10 taken along line C2-C2′ in FIG. 5.

Referring to FIG. 5, FIG. 6, and FIG. 7, the image sensor 10, for example, as shown in FIG. 1, further includes a color filter array including a first color filter 200R and a second color filter 200G. The color filter array is disposed over a light receiving surface 100T of a semiconductor substrate 100. The image sensor 10 further includes the micro-lens array including a first lens 300R and a second lens 300G. The micro-lens array is disposed on the color filter array.

The first color filter 200R is disposed over the light receiving surface 100T of the semiconductor substrate 100 to substantially overlap the first pixel group 100R. The first color filter 200R is disposed over the first shared region 120R and the first pixel regions 110R to substantially overlap the first shared region 120R and the first pixel regions 110R in the Z-axis direction. The first lens 300R is disposed over the first color filter 200R to substantially overlap the first color filter 200R in the Z-axis direction. Optical stacks each including the first color filter 200R and the first lens 300R are disposed over the semiconductor substrate 100. In the example of the pixel structure, one first color filter 200R shares four adjacent first pixel regions 110R, four adjacent first pixel regions 110R share one first shared region 120R, and one first lens 300R covers four adjacent first pixel regions 110R and the one first shared region 120R. The pixel structure may be an all 4-coupled (A4C) sensor structure that divides each pixel group into four pixel regions. The pixel structure is designed to detect phase differences both horizontally and vertically. In some implementations, the pixel structure performs a phase detection auto focusing (PDAF) function in up/down/left/right directions or in the X-axis and Y-axis directions.

The second color filter 200G is disposed over the light receiving surface 100T of the semiconductor substrate 100 to substantially overlap the second pixel group 100G. The second color filter 200G is disposed over the second shared region 120G and the second pixel regions 110G to substantially overlap the second shared region 120G and the second pixel regions 110G in the Z-axis direction. The second lens 300G is disposed over the second color filter 200G to substantially overlap the second color filter 200G in the Z-axis direction. Optical stacks each including the second color filter 200G and the second lens 300G are disposed over the semiconductor substrate 100. In the example of the pixel structure, one second color filter 200G shares four adjacent second pixel regions 110G, four adjacent second pixel regions 110G share one second shared region 120G, and one second lens 300G covers four adjacent second pixel regions 110G and one second shared region 120G.

A first width D1 of the first shared region 120R overlapping with the first color filter 200R and the first lens 300R is different from a second width D2 of the second shared region 120G overlapping with the second color filter 200G and the second lens 300. The widths D1 and D2 of the shared regions 120R and 120G are different for the color filters 200R and 200G. As a result, difference in light sensitivity of the pixel regions 110R and 110G for each of the color filters 200R and 200G can be reduced.

In an embodiment, when the first color filter 200R is a red color filter and the second color filter 200G is a green color filter, the first width D1 of the first shared region 120R may be smaller than the second width D2 of the second shared region 120G. Accordingly, the difference in first light sensitivity detected in the first pixel regions 110R when light passes through the first color filter 200R, which is the red color filter, and second light sensitivity detected in the second pixel regions 110G when light passes through the second color filter 200G, which is the green color filter, can be reduced.

In an embodiment, when the first color filter 200R is a red color filter and the second color filter 200G is a blue color filter, the first width D1 of the first shared region 120R for the red color may be smaller than the second width D2 of the second shared region 120G for the green color. In an embodiment, when the first color filter 200R is a green color filter and the second color filter 200G is a blue color filter, the first width D1 of the first shared region 120R may be smaller than the second width D2 of the second shared region 120G.

A grid 210 is further disposed between the first color filter 200R and the second color filter 200G to separate the first and second color filters from each other. The grid 210 reduces cross-talk between pixel regions caused by light incident on the first color filter 200R entering the second pixel region 110G located below the second color filter 200G. The grid 210 includes a metal layer such as tungsten (W) layer, or an air-grid structure including an empty space filled with an air.

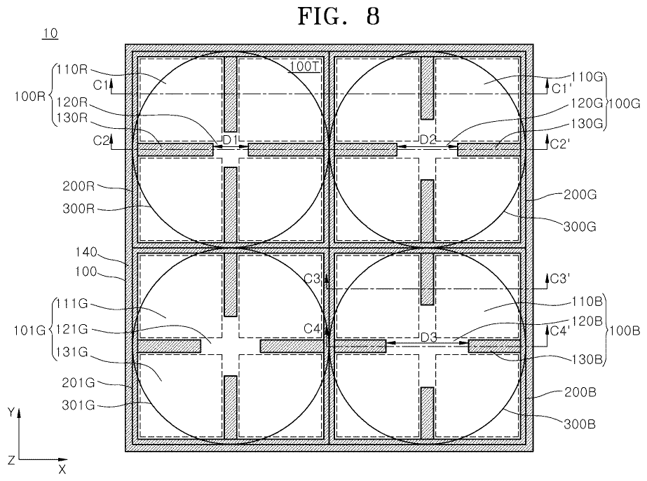

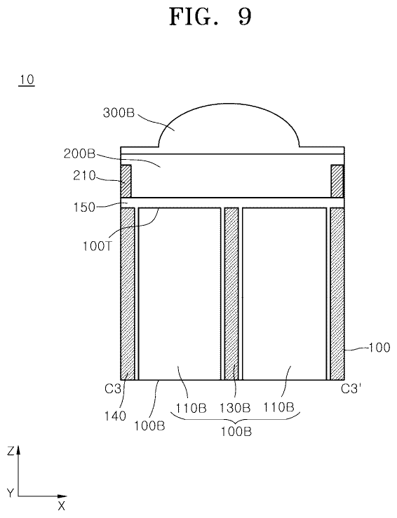

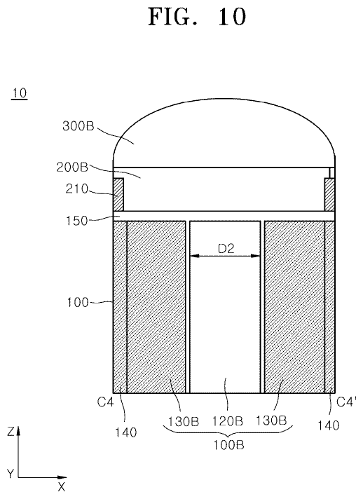

FIG. 8 is a schematic view illustrating an image sensor 10 according to an embodiment of the present disclosure. FIG. 8 schematically illustrates a pixel array, a color filter array, and a micro-lens array of the image sensor 10 according to an embodiment. FIG. 9 is a schematic cross-sectional view illustrating a cross-sectional shape of the image sensor 10 taken along line C3-C3′ in FIG. 8. FIG. 10 is a schematic cross-sectional view illustrating a cross-sectional shape of the image sensor 10 taken along line C4-C4′ in FIG. 8. The cross-sectional shape of the image sensor 10 along the line C1-C1′ of FIG. 8 may be presented as in FIG. 6. The cross-sectional shape of the image sensor 10 along the line C2-C2′ of FIG. 8 may be presented as in FIG. 7.

Referring to FIG. 8, FIG. 9, and FIG. 10 together with FIG. 6 and FIG. 7, the image sensor 10 includes a semiconductor substrate 100 including pixel arrays, the color filter array, and the micro-lens array. In the implementations, the pixel arrays, the color filter arrays, and the micro-lens arrays are arranged in rows and columns. The pixel array includes a plurality of pixel regions 110R, 110G, and 110B disposed within the semiconductor substrate 100. The pixel array includes first, second, and third pixel groups 100R, 100G, and 100B. The first pixel group 100R and the second pixel group 100G are disposed side by side in a first direction, that is the X-axis direction, and the second pixel group 100G and the third pixel group 100B are disposed side by side in a second direction, that is the Y-axis direction. The pixel array further includes a fourth pixel group 101G disposed parallel to the first pixel group 100R in the second direction, that is, the Y-axis direction, within the semiconductor substrate 100. The fourth pixel group 101G may be configured substantially identically to the second pixel group 100G.

The pixel groups 100R, 100G, 100B, and 101G are separated from each other by an outer isolation wall 140 in the semiconductor substrate 100. The first pixel group 100R includes first inner isolation walls 130R, a first shared region 120R, and first pixel regions 110R, the second pixel group 100G includes second inner isolation walls 130G, a second shared region 120G, and second pixel regions 110G, the third pixel group 100B includes third inner isolation walls 130B, a third shared region 120B, and third pixel regions 110B, and the fourth pixel group 101G includes fourth inner isolation walls 131G, a fourth shared region 121G, and fourth pixel regions 111G. The outer isolation wall 140, the first inner isolation walls 130R, the second inner isolation walls 130G, the third inner isolation walls 130B, and the fourth inner isolation walls 131G constitute an isolation structure that separates the pixel regions.

The semiconductor substrate 100 includes the plurality of first pixel regions 110R connected through the first shared region 120R, the plurality of second pixel regions 110G connected through the second shared region 120G, and the plurality of third pixel regions 110B connected through the third shared region 120B. The semiconductor substrate 100 further includes the plurality of fourth pixel regions 111G connected through the fourth shared region 121G. The plurality of first inner isolation walls 130R extend between neighboring first pixel regions 110R while opening the first shared region 120R within the semiconductor substrate 100. A plurality of second inner isolation walls 130G extend between neighboring second pixel regions 110G while opening the second shared region 120G within the semiconductor substrate 100. The plurality of third inner isolation walls 130B extend between neighboring third pixel regions 110G while opening the third shared region 120B within the semiconductor substrate 100. The plurality of fourth inner isolation walls 131G extend between neighboring fourth pixel regions 111G while opening the fourth shared region 121G within the semiconductor substrate 100.

The color filter array is disposed over the semiconductor substrate 100. A first color filter 200R is disposed over the first shared region 120R and the first pixel regions 110R of the first pixel group 100R, a second color filter 200G is disposed over the second shared region 120G and the second pixel regions 110G of the second pixel group 100G, a third color filter 200B is disposed over the third shared region 120B and the third pixel regions 110B of the third pixel group 100B, and a fourth color filter 201G is disposed over the fourth shared region 121G and the fourth pixel regions 111G of the fourth pixel group 101G. The arrangement of the color filter array with the first color filter 200R, the second color filter 200G, the third color filter 200B and the fourth color filter 201G of different colors in adjacent four pixel regions is configured to provide color sensing or capturing function in the image sensor in FIG. 8 so such adjacent four pixel regions form a color sensing pixel group. The first color filter 200R, the second color filter 200B, and the third color filter 200B are filters of different colors. In an embodiment for implementing a Bayer color filter array with 50% green, 25% red, and 25% blue for capturing coloring of an image in the incident light, the first color filter 200R includes a red color filter, the second color filter 200G includes a green color filter, and the third color filter 200B includes a blue color filter, and the fourth color filter 201G includes a green color filter.

The first inner isolation walls 130R and the second inner isolation walls 130G are disposed in the semiconductor substrate 100 such that a first width D1 between facing first inner isolation walls 130R of the first shared region 120R is smaller than a second width D2 between facing second inner isolation walls 130G of the second shared region 120G. In addition, the first inner isolation walls 130R and the third inner isolation walls 130B are disposed in the semiconductor substrate 100 such that the first width D1 between the facing first inner isolation walls 130R of the first shared region 120R is smaller than a third width D3 between facing third inner isolation walls 130B of the third shared region 120B.

The third width D3 is a spacing between ends of the facing third inner isolation walls 130B in the same manner as the first width D1 and the second width D2 are set. In an embodiment, the first inner isolation walls 130R, the second inner isolation walls 130G, and the third inner isolation walls 130B extend in directions from the outer isolation wall 140 toward the first shared region 120R, the second shared region 120G, and the third shared region 120B, respectively.

The first width D1 of the first shared region 120R is a spacing between ends of the facing first inner isolation walls 130R in a direction in which the first inner isolation walls 130R extend. The second width D2 of the second shared region 120G is a spacing between ends of the facing second inner isolation walls 130G in a direction in which the second inner isolation walls 130G extend, and the third width D3 of the third shared region 120B is a spacing between ends of the facing third inner isolation walls 130B in a direction in which the third inner isolation walls 130B extend.

The micro-lens array is disposed on the color filter array. The micro-lens array includes a first lens 300R disposed on the first color filter 200R, a second lens 300G disposed on the second color filter 200G, and a third lens 300B disposed on the third color filter 200B. The micro-lens array further includes a fourth lens 301G disposed on the fourth color filter 201G.

The first width D1 of the first shared region 120R is different from the second width D2 of the second shared region 120G and the third width D3 of the third shared region 120B. Accordingly, difference between light sensitivity received from the first pixel regions 110R overlapping the first color filter 200R and the light sensitivity received from the second pixel regions 110G overlapping the second color filter 200G or the light sensitivity received from the third pixel regions 110B overlapping the third color filter 200B is reduced. Because the light passing through the red color filter, the green color filter, and the blue color filter have different wavelengths, the light sensitivities received from the pixel regions 110R, 110G, and 110B may differ.

When the first color filter 200R overlapping the first shared region 120R includes the red color filter and the second color filter 200G overlapping the second shared region 120G includes the green color filter, the light sensitivity received from the second pixel regions 110G overlapping the green color filter is lower than the light sensitivity received from the first pixel regions 110R overlapping the red color filter. The first width D1 of the first shared region 120R is smaller than the second width D2 of the second shared region 120G, that is, the second width D2 of the second shared region 120G is larger than the first width D1 of the first shared region 120R. Accordingly, the number of electrons photoelectrically converted in the second shared region 120G is relatively increased, thereby increasing the number of electrons distributed to the second pixel regions 110G. Accordingly, the light sensitivity received from the second pixel regions 110G can be improved.

When the first color filter 200R overlapping the first shared region 120R includes a red color filter and the third color filter 200B overlapping the third shared region 120B includes a blue color filter, the light sensitivity received from the third pixel regions 110B overlapped with the blue color filter is lower than the light sensitivity received from the first pixel regions 110R overlapped with the red color filter. The first width D1 of the first shared region 120R is smaller than the third width D3 of the third shared region 120G, thereby improving the light sensitivity received from the third pixel regions 110B.

The light sensitivity received from the third pixel regions 110B overlapped with the blue color filter is lower than the light sensitivity received from the second pixel regions 110G overlapped with the green color filter. The second width D2 of the second shared region 120G is smaller than the third width D3 of the third shared region 120G, thereby improving the light sensitivity received from the third pixel regions 110B.

In this way, by making the first width D1 of the first shared region 120R different from the second width D2 of the second shared region 120G and the third width D3 of the third shared region 120B, the difference in light sensitivity between color filters can be reduced.

Referring to FIG. 6 and FIG. 7, a degree to which the first pixel regions 110R overlapped with the first lens 300R and the first color filter 200R separate the image may be evaluated as a separation ratio. Chief ray angle (CRA) of the light entering the first lens 300R is +10 degrees (°) and −10 degrees (°), and the ratio of signal intensity of the light received from the left pixel region among the first pixel regions 110R and the signal intensity of the light received from the right pixel region among the first pixel regions 110R may be evaluated as the separation ratio. From experimental observations, it may be checked that the separation ratio tends to decrease as the light incident on the first pixel regions 110R has a longer wavelength, and the separation ratio tends to decrease as the first width D1 of the first shared region 120R increases.

Referring to FIG. 6 and FIG. 9, when the first color filter 200R is a red color filter, the second color filter 200G is a green color filter, and the third color filter 200B is a blue color filter, the separation ratios observed in the first pixel regions 110R, the second pixel regions 110G, and the third pixel regions 110B may be different from each other. By making the first width D1 of the first shared region 120R smaller than the second width D2 of the second shared region 120G or the third width D3 of the third shared region 120B, the difference in separation ratio can be reduced. Because the separation ratios observed in the second pixel regions 110G and the third pixel regions 110B are different or similar, the second width D2 of the second shared region 120G may be made smaller than the third width D3 of the third shared region 120B to compensate for the difference in the observed separation ratios, or the second width D2 of the second shared region 120G may be made similar to the third width D3 of the third shared region 120B.

When the first width D1 of the first shared region 120R, the second width D2 of the second shared region 120G, and the third width D3 of the third shared region 120B are the same, that is, when the widths D1, D2, and D3 of the shared regions 120R, 120G, and 120B are the same for each color filter, the separation ratios observed in the first pixel regions 110R, the second pixel regions 110G, and the third pixel regions 110B may vary depending on wavelengths filtered by the color filters. When the separation ratios observed in the first pixel regions 110R, the second pixel regions 110G, and the third pixel regions 110B are different, there may be difficulty in precisely changing the overlapping positions of the color filters to be overlapped in each of the first pixel regions 110R, the second pixel regions 110G, and the third pixel regions 110B in order to compensate for the difference in the separation ratios. By applying the first width D1 of the first shared region 120R, the second width D2 of the second shared region 120G, and the third width D3 of the third shared region 120B differently for each color filter, the difference in the separation ratios can be reduced. Accordingly, it is possible to overcome the difficulty of precisely changing the overlapping positions of the color filters to be overlapped with the first pixel regions 110R, the second pixel regions 110G, and the third pixel regions 110B.

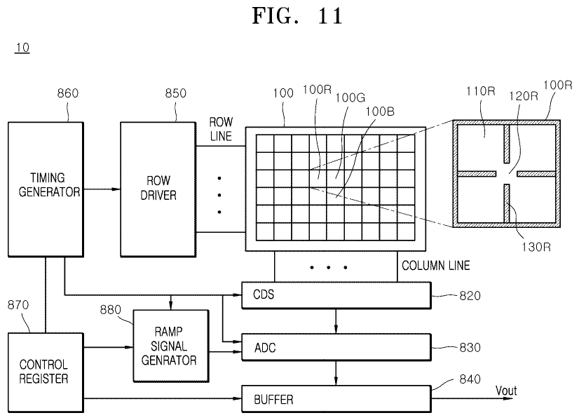

FIG. 11 is a schematic view illustrating an image sensor 10 according to an embodiment of the present disclosure.

Referring to FIG. 11, the image sensor 10 further includes circuit elements that drive pixel arrays including pixel groups 110R, 110G, and 100B. In an embodiment, a first pixel group 100R includes first pixel regions 100R, a first shared region 120R, and first inner isolation walls 130R. The circuit elements are disposed on a semiconductor substrate 100. The circuit elements include a correlated double sampler (CDS) 820, an analog-digital converter (ADC) 830, a buffer 840, a row driver 850, a timing generator 860, a control register 870, and a ramp signal generator 880.

The pixel groups 100R, 100G, and 100B or pixel regions including the first pixel regions 100R convert optical image information into electrical image signals and transmit the electrical image signals to the correlated double sampler 820 via column lines. Each of the plurality of pixel regions is connected to one of row lines and one of the column lines.

The correlated double sampler 820 holds and samples the electrical image signals received from the pixel regions. For example, the correlated double sampler 820 samples a reference voltage level and a voltage level of the received electrical image signal according to a clock signal provided from the timing generator 860 and transmits an analog signal corresponding to a difference between the reference voltage level and the voltage level of the received electrical image signal to the analog-digital converter 830. The analog-digital converter 830 converts the received analog signal into a digital signal and transmit the digital signal to the buffer 840.

The buffer 840 latches the received digital signal and sequentially outputs the digital signal to an image signal processing element (not shown). The buffer 840 includes a memory that latches the digital signal and a sense amplifier that amplifies the digital signal. The row driver 850 drives the pixel regions according to signals from the timing generator 860. For example, the row driver 850 generates selection signals for selecting one row line among the plurality of row lines and/or driving signals for driving the one row line.

The timing generator 860 generates timing signals for controlling the correlated double sampler 820, the analog-digital converter 830, the row driver 850, and the ramp signal generator 880. The control register 870 generates control signals for controlling the buffer 840, the timing generator 860, and the ramp signal generator 880. The ramp signal generator 880 generates a ramp signal for controlling an image signal output from the buffer 840 according to control of the timing generator 860.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. An image sensor comprising:
a semiconductor substrate including a plurality of first pixel regions connected to a first shared region and a plurality of second pixel regions connected to a second shared region, each of the first pixel regions and second pixel regions structured to detect incident light to generate an electrical pixel signal representing the detected incident light;
a plurality of first inner isolation walls extending between neighboring first pixel regions within the semiconductor substrate and disposed to provide a first opening that exposes the first shared region; and
a plurality of second inner isolation walls extending between neighboring second pixel regions within the semiconductor substrate and disposed to provide a second opening that exposes the second shared region,
wherein a first width of the first opening in the first shared region and between facing first inner isolation walls is different from a second width of the second opening in the second shared region and between facing second inner isolation walls.

2. The image sensor of claim 1, further comprising an outer isolation wall that surrounds outer perimeters of the first pixel regions and the second pixel regions.

3. The image sensor of claim 2, wherein each of the first inner isolation walls and the second inner isolation walls extends from the outer isolation wall to the first shared region and the second shared regions, respectively.

4. The image sensor of claim 2, wherein the first inner isolation walls are disposed radially with respect to the first shared region and extend from the outer isolation wall to the first shared region.

5. The image sensor of claim 2,
wherein the outer isolation wall extends in a first direction and a second direction intersecting the first direction; and
wherein the first inner isolation walls and the second inner isolation walls extend in the first direction and the second direction.

6. The image sensor of claim 3,
wherein the first width in the first shared region is a spacing between ends of the facing first inner isolation walls in a direction in which the facing first inner isolation walls extend; and
wherein the second width in the second shared region is a spacing between ends of the facing second inner isolation walls in which the facing second inner isolation walls extend.

7. The image sensor of claim 1, wherein the semiconductor substrate includes a light receiving surface and an opposite surface to the light receiving surface.

8. The image sensor of claim 7, wherein the first inner isolation walls and the second inner isolation walls extend from the light receiving surface to the opposite surface.

9. The image sensor of claim 1, wherein the first pixel regions are disposed to surround the first shared region with the first shared region at a center.

10. The image sensor of claim 7,
wherein the first pixel regions are disposed such that four first pixel regions surround the first shared region with the first shared region at a center on the light receiving surface; and
wherein the second pixel regions are disposed such that four second pixel regions surround the second shared region with the second shared region at a center on the light receiving surface.

11. The image sensor of claim 1, further comprising:
a first color filter disposed on the first shared region and the first pixel regions; and
a second color filter disposed on the second shared region and the second pixel regions.

12. The image sensor of claim 11,
wherein the first color filter includes a red color filter;
wherein the second color filter includes a blue color filter; and
wherein the first width is smaller than the second width.

13. The image sensor of claim 11,
wherein the first color filter includes a red color filter;
wherein the second color filter includes a green color filter; and
wherein the first width is smaller than the second width.

14. The image sensor of claim 11,
wherein the first color filter includes a green color filter;
wherein the second color filter includes a blue color filter; and
wherein the first width is smaller than the second width.

15. The image sensor of claim 11, further comprising a micro-lens array including a first lens disposed on the first color filter and a second lens disposed on the second color filter.

16. The image sensor of claim 2,
wherein the semiconductor substrate includes a light receiving surface and an opposite surface to the light receiving surface; and
wherein the outer isolation wall extends from the light receiving surface to the opposite surface.

17. An image sensor comprising:
a semiconductor substrate including a plurality of first pixel regions connected to a first shared region, a plurality of second pixel regions connected to a second shared region, and a plurality of third pixel regions connected to a third shared region;
a plurality of first inner isolation walls extending between neighboring first pixel regions within the semiconductor substrate and providing a first opening that exposes the first shared region;
a plurality of second inner isolation walls extending between neighboring second pixel regions within the semiconductor substrate and providing a second opening that exposes the second shared region;
a plurality of third inner isolation walls extending between neighboring third pixel regions within the semiconductor substrate and providing a third opening that exposes the third shared region;
a first color filter disposed on the first shared region and the first pixel regions;
a second color filter disposed on the second shared region and the second pixel regions; and
a third color filter disposed on the third shared region and the third pixel regions,
wherein a first width of the first opening in the first shared region and between facing first inner isolation walls is smaller than a second width of the second opening in the second shared region and between facing second inner isolation walls and a third width of the third opening and between facing third inner isolation walls.

18. The image sensor of claim 17, wherein the third width is smaller than the second width.

19. The image sensor of claim 17, wherein the third width is substantially equal to the second width.

20. The image sensor of claim 17,
wherein the first color filter includes a red color filter;
wherein the second color filter includes a green color filter; and
wherein the third color filter includes a blude color filter.
